(19) United States
(12) Patent Application Publication
(10) Pub. No.: US 2013/0242523 A1
(43) Pub. Date: Sep. 19, 2013

(54) DEPLOYABLE IN-FLIGHT ENTERTAINMENT MONITOR

(71) Applicant: B/E AEROSPACE, INC., Wellington, FL (US)

(72) Inventors: Andrew Gordon Wallace, Nr. Newant (GB); Paul Benedict Rutter, Warwick (GB); Andrew David Mitchell, Leamington Spa (GB); Glenn Allen Johnson, Rural Hall, NC (US)

(73) Assignee: B/E Aerospace, Inc., Wellington, FL (US)

(21) Appl. No.: 13/803,184

(22) Filed: Mar. 14, 2013

Related U.S. Application Data
(60) Provisional application No. 61/610,514, filed on Mar. 14, 2012.

(51) Int. Cl. B60R 11/02; H05K 7/00

(52) U.S. Cl. CPC B60R 11/0235; H05K 7/00
USPC 361/807; 297/217.3

(57) ABSTRACT

A deployable in-flight entertainment monitor attached to a supporting fixture and configured to move between a stowed position wherein the monitor is in a portrait orientation, to a deployed position wherein the monitor is in a landscape orientation, wherein in the deployed position a portion of the monitor overhangs the supporting fixture.

### CROSS-REFERENCE TO RELATED APPLICATION

This application claims priority to U.S. Application No. 61/610,514 filed Mar. 14, 2012, the contents of which are incorporated by reference herein.

### TECHNICAL FIELD AND BACKGROUND OF THE INVENTION

The present invention relates to the field of passenger aircraft, and more particularly, to in-flight entertainment monitors located within a passenger cabin. This invention relates to a deployable in-flight entertainment monitor mounted on a support mechanism that permits the monitor to be either manually or automatically deployed, from a portrait to a landscape orientation, as desired.

Aircraft passenger cabins may include in-flight entertainment monitors. Such monitors typically provide passengers with both information concerning the flight, as well as entertainment. Flight information may include safety information, flight progress information, destination information, weather information, and the like. Entertainment may include television programming, movies, music, commercial advertisements, video games, internet access, and the like.

In-flight entertainment monitors are typically fixed to a variety of objects within the passenger cabin for viewing purposes within the cabin. For instance, in-flight entertainment monitors may be fixed to seat backs, bulkhead walls or partitions. When attached to seat backs, in-flight entertainment monitors are typically fixed in their landscape orientation and face rearward for the benefit and use of an aft-seated passenger. For privacy purposes, premium class seating may include partitions separating seats, beds and/or seating areas. When positioned on such partitions, in-flight entertainment monitors are typically fixed in their landscape orientation and attached to a rearward portion of a partition facing the passenger. Similarly, in-flight entertainment monitors are typically positioned on bulkhead walls located at various points within the passenger cabin.

In the field of passenger aircraft, it is desirable for in-flight entertainment monitors to be as large as possible and practical for the purposes of visual entertainment purposes and communicating information to passengers. A larger size may also provide a larger image for those passengers with impaired vision. Having a larger display size is especially desirable for premium class seating. However, within passenger aircraft, space is limited. Also, for passenger safety during boarding and exiting the aircraft and during periods of turbulence, it is desirable that fixtures, such as in-flight entertainment monitors, not protrude from the objects and fixtures to which they are attached. Such protrusions may hinder ingress and egress from a seating or other passenger area. As such, the size of the display may be limited by the object to which it is fixed so as not to protrude from the object and so as not to consume valuable space.

Further, depending on the particular entertainment or information displayed, it may be desirable to have the in-flight entertainment monitor fixed in a portrait orientation. Similarly, it may be desirable to have the in-flight entertainment monitor fixed in the landscape orientation. It may also be desirable to provide the option of displaying in either portrait or landscape orientation.

Accordingly, there is a need in the art for a large display in-flight entertainment monitor that is deployable in both a portrait and a landscape orientation depending on various in-flight applications. Further, there is a need in the art for an in-flight entertainment monitor that does not protrude or otherwise impede passenger safety. There is also a need in the art for an in-flight entertainment monitor that accomplishes these tasks that may still be attached to various different objects and fixtures such as seat backs, bulkhead walls and seat partitions within the aircraft.

### SUMMARY OF THE INVENTION

It is therefore an object of the present invention to provide a deployable in-flight entertainment monitor that is mounted on a support mechanism that permits the monitor to be either manually, remotely or automatically deployed from a stowed position to a deployed position as desired.

It is a further object of the invention to provide a deployable in-flight entertainment monitor that can be mounted without overhangs or protrusions onto an aircraft fixture such as a partition, seatback or bulkhead wall that is smaller in width than the length of the display in its deployed, viewing orientation.

It is a further object of the invention to provide a deployable in-flight entertainment monitor in which, in its normally stowed position, the monitor is positioned vertically in a portrait aspect ratio to display to the passenger in-flight information, but can be deployed into a full in-flight entertainment mode with a landscape, wide screen orientation.

These and other objects and advantages of the invention are achieved by providing a deployable in-flight entertainment monitor including an aircraft fixture having a rearward facing surface and a monitor attached to the rearward facing surface of the aircraft fixture. The monitor operates from a stowed position, where the monitor is in a portrait orientation for the display of information, to a deployed position, where the monitor is in a landscape orientation for the display of entertainment. Control guide ways are attached to the rear of the monitor. The control guide ways have circular pathways that support the attachment of the monitor to the aircraft fixture and that facilitate the operation of the monitor from the stowed position to the deployed position.

According to another embodiment of the invention, when the monitor is in the stowed position, a stowed vertical height of the monitor may be longer than a horizontal width of the aircraft fixture and a stowed horizontal width of the monitor may be shorter than the horizontal width of the aircraft fixture. Further, in the deployed position, a deployed horizontal width of the monitor may be longer than the horizontal width of the aircraft fixture.

According to another embodiment of the invention, in the stowed position, the monitor may not overhang from the aircraft fixture.

According to another embodiment of the invention, in the deployed position, the monitor may overhang from the aircraft fixture.

According to another embodiment of the invention, the aircraft fixture may be a partition, a seat back or a bulkhead wall.

According to another embodiment of the invention, the monitor may operate from the stowed position to the deployed position and from the deployed position to the stowed position by a manual operation performed by a passenger.

According to another embodiment of the invention, the monitor may operate from the stowed position to the deployed position and from the deployed position to the stowed position by an automatic operation.

According to another embodiment of the invention, the monitor may operate from the stowed position to the deployed position and from the deployed position to the stowed position by a remote automatic operation of an aircraft crew member.

According to another embodiment of the invention, there may be a total of two control guide ways.

According to another embodiment of the invention, there may be a total of three control guide ways.

### BRIEF DESCRIPTION OF THE DRAWINGS

The present invention is best understood when the following detailed description of the invention is read with reference to the accompanying drawings, in which:

FIG. 1 is a perspective view of a first class-type aircraft passenger seating area, including an in-flight entertainment monitor attached to a partition according to an embodiment of the invention;

FIG. 2 is an elevation view of the in-flight entertainment monitor in its deployed, horizontal, landscape orientation;

FIGS. 3 and 4 are elevation views of the in-flight entertainment monitor in a transition position from the landscape wide screen deployed position to a portrait vertical stowed position; and

FIG. 5 is an elevation view of the in-flight entertainment monitor in its portrait vertical stowed position.

### DESCRIPTION OF THE PREFERRED EMBODIMENT AND BEST MODE

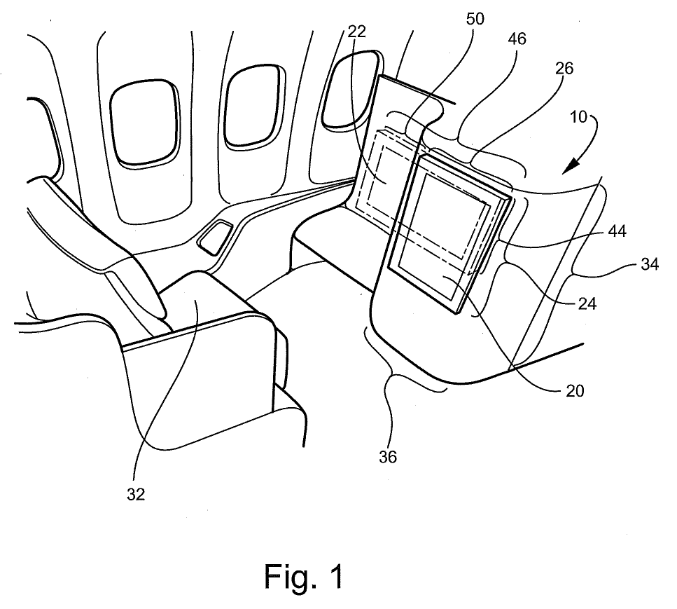

Referring now specifically to the drawings, an in-flight entertainment monitor is shown generally at reference numeral 10. Referring to FIG. 1, the in-flight entertainment monitor 10 is configured to move and operate from a vertical portrait stowed position 20 to a horizontal landscape deployed position 22. The in-flight entertainment monitor 10 is attached to a rearward facing portion of an aircraft fixture that may be a seat partition 30. An aircraft passenger seated in the aircraft passenger seat 32 may observe information displayed on the in-flight entertainment monitor 10 when the monitor is in the stowed position 20. An aircraft passenger seated in the aircraft passenger seat 32 may observe entertainment displayed on the in-flight entertainment monitor 10 when the monitor is in the deployed position 22.

The seat partition 30 is defined by a height 34 and a width 36. In the stowed position 20, the monitor 10 is defined by a stowed height 24 and a stowed width 26. The stowed width 26 of the monitor 10 in the stowed position 20 is less than the width 36 of the partition 30. The stowed width 26 of the monitor 10 does not overhang the partition 30.

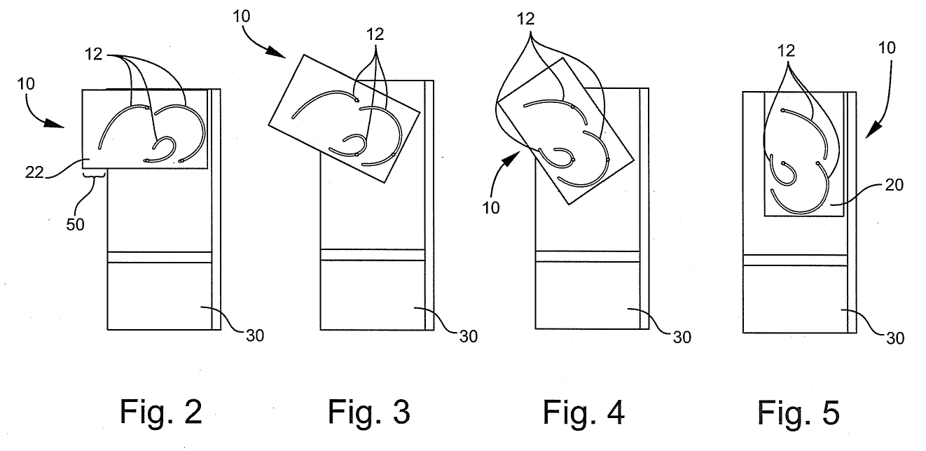

Once the monitor 10 has operated from the stowed position 20, as shown in FIG. 5, to the deployed position 22, as shown in FIG. 2, the monitor 10 is defined by a deployed height 44 and a deployed width 46. The deployed height 44 of the monitor 10 is equal in length to the stowed width 26 of the monitor 10. The deployed width 46 of the monitor 10 is equal to the stowed height 24 of the monitor 10. The deployed width 46 of the monitor 10 is greater than the width 36 of the partition 30. The deployed width 46 of the monitor 10 overhangs 50 the partition 30.

Referring to FIGS. 2-5, the monitor 10 includes a support mechanism in the form of control guide ways 12. The guide ways 12 may be driven by a driving gear pinion (not shown) that allows the monitor 10 to be either automatically or manually deployed between the stowed position 20 and the deployed position 22. This deployable capability enables the monitor 10 to be mounted in the stowed position 20 without overhangs 50 or protrusions onto a partition 30 that is smaller in width 36 than the width 46 of the monitor 10 in its deployed position 22. In its normally stowed position 20 shown in FIG. 5, the monitor 10 is positioned vertically in a portrait aspect ratio. In this stowed position 20 it can be used to display to the passenger seated in aircraft seat 32 a range of in-flight information. However, when full in-flight entertainment functionality is required, the passenger seated in seat 32, as shown in FIG. 1, will deploy the monitor 10 from its stowed position 20, as shown in FIG. 5, into a landscape/wide-screen deployed position 22, as shown in FIG. 2. This deployment can be achieved in a number of ways.

In one preferred embodiment, the guide ways 12 may include a circular arc toothed rack mounted on the back of the monitor 10 which meshes with a motorized pinion gear to drive the monitor 10 between its stowed 20 and deployed 22 positions. The curved guide ways 12 support the monitor 10 and guide its travel during deployment and retraction as shown in FIGS. 2-5. The drive is reversible and can be used to both deploy and retract the monitor 10.

Referring to FIGS. 2-5, the movement of the monitor 10 from the deployed landscape orientation to the stowed portrait orientation is shown in consecutive steps. Comparing FIGS. 2 and 5, the monitor does not simply pivot about a single point, but translates while rotating. This is evidenced by the fact that the ‘top’ of the monitor 10 is aligned with the top of the partition 30 in FIG. 2 when the monitor is in landscape, and the ‘side’ of the monitor is aligned with the top of the partition 30 in FIG. 5 when the monitor is in portrait. Thus, the monitor 10 both rotates and translates as it moves between the stowed and deployed positions. The degree of vertical and horizontal translation is controlled by the shapes of the guide ways 12, which are slots. The shape, position and length of the guide slots can be tailored to customize the translation movement. The number of guide ways 12 and monitor supports may also be customized depending on the size, weight and shape of the monitor.

In an alternative embodiment, the rack and pinion arrangement may be replaced with a powered actuator acting on a pin and bearing running in a third guide way. In yet another preferred embodiment, a spring and damper arrangement may be used to achieve the monitor 10 deployment once a latch is released. The monitor 10 is then returned to its stowed position 20 and latched manually.

A deployable in-flight entertainment monitor 10 according to the invention has been described with reference to specific embodiments and examples. Various details of the invention may be changed without departing from the scope of the invention. Furthermore, the foregoing description of the preferred embodiments of the invention and best mode for practicing the invention are provided for the purpose of illustration only and not for the purpose of limitation, the invention being defined by the claims.

What is claimed is:

1. A deployable in-flight entertainment monitor comprising:
a fixture having a supporting surface;
a monitor attached to the supporting surface of the fixture and moveable relative thereto between a stowed position wherein the monitor is in a portrait orientation to a deployed position wherein the monitor is in a landscape orientation; and
a plurality of control guide ways attached to the rear of the monitor supporting the attachment of the monitor to the fixture and controlling movement of the monitor from the stowed position to the deployed position.

2. The deployable in-flight entertainment monitor of claim 1, wherein in the stowed position, a stowed vertical height of the monitor is longer than a horizontal width of the fixture and a stowed horizontal width of the monitor is shorter than the horizontal width of the fixture, and in the deployed position a deployed horizontal width of the monitor is longer than the horizontal width of the fixture.

3. The deployable in-flight entertainment monitor of claim 1, wherein in the stowed position, the monitor does not overhang the fixture.

4. The deployable in-flight entertainment monitor of claim 3, wherein in the deployed position, the monitor overhangs from aircraft fixture.

5. The deployable in-flight entertainment monitor of claim 1, wherein the monitor rotates, translates horizontally, and translates vertically as the monitor moves between the stowed and deployed positions.

6. The deployable in-flight entertainment monitor of claim 1, wherein the aircraft fixture is one of a seat back, bulkhead wall and partition.

7. The deployable in-flight entertainment monitor of claim 1, further comprising three guide ways for controlling rotational and translation movement of the monitor with respect to the fixture, each of the guide ways defining an arcuate path.

8. A deployable in-flight entertainment monitor, comprising:
an aircraft fixture having a rearward facing surface defined by a height and a width;
a monitor attached to the rearward facing surface of the aircraft fixture that moves by way of combined rotational and translation motion between a stowed position in which the monitor is in a portrait orientation and is within the width of the aircraft fixture, and a deployed position in which the monitor is in a landscape orientation and overhangs the width of the aircraft fixture; and
a plurality of control guide ways attached to the rear of the monitor, each of the control guide ways defining a circular pathway guiding the combined rotational and translational motion of the monitor.

9. The deployable in-flight entertainment monitor of claim 8, wherein the monitor rotates, translates horizontally, and translates vertically as the monitor moves between the stowed and deployed positions.

10. The deployable in-flight entertainment monitor of claim 8, wherein the fixture is one of a seat back, partition and bulkhead wall.

11. The deployable in-flight entertainment monitor of claim 8, wherein the monitor moves from the stowed position to the deployed position and from the deployed position to the stowed position manually.

12. The deployable in-flight entertainment monitor of claim 8, wherein the monitor moves from the stowed position to the deployed position and from the deployed position to the stowed position automatically.

13. The deployable in-flight entertainment monitor of claim 8, wherein the number of guide ways is three.

14. The deployable in-flight entertainment monitor of claim 8, wherein the number of guide ways is two.
